(19) United States
(12) Patent Application Publication
(10) Pub. No.: US 2025/0271752 A1
(43) Pub. Date: Aug. 28, 2025

(54) APPARATUSES, SYSTEMS, AND METHODS FOR FABRICATION OF THREE-LEVEL STRUCTURES

(71) Applicant: Quantinuum LLC, Broomfield, CO (US)

(72) Inventors: Adam Jay Ollanik, Boulder, CO (US); Mary A. Rowe, Boulder, CO (US)

(21) Appl. No.: 19/048,529

(22) Filed: Feb. 7, 2025

Related U.S. Application Data
(60) Provisional application No. 63/557,398, filed on Feb. 23, 2024.

(51) Int. Cl. G03F 7/00; G02B 6/34; G06N 10/40

(52) U.S. Cl. CPC G03F 7/0005; G02B 6/34; G03F 7/0017; G03F 7/0035; G06N 10/40

(57) ABSTRACT

Example embodiments provide methods, systems, apparatuses, computer program products and/or the like for fabrication of three-level structures. In various embodiments, the three-level structures are at least part of photonic structures or elements. For example, a three-level structure may be part of grating coupler or other photonic element. In various embodiments, three-level structures are structures with three levels of material thickness: no material, thin material, and thick material. In various embodiments, the fabrication method described herein is deterministic and easily controllable.

### CROSS-REFERENCE TO RELATED APPLICATION(S)

This Application claims priority to U.S. Application No. 63/557,398, filed Feb. 23, 2024, the contents of which are incorporated herein by reference in their entireties.

### TECHNICAL FIELD

Various embodiments relate to apparatuses, systems, and methods relating to and/or including fabrication of three-level structures. Various embodiments relate to photonic elements that include three-level structures. An example embodiment relates to confined object quantum computing (e.g., quantum charge-coupled device (QCCD)-based quantum computing) wherein three-level structures are disposed and/or formed on a surface of an atomic object containment apparatus of a confined object quantum computer.

### BACKGROUND

Grating couplers are a common photonic component and can be used to couple light into or out of a waveguide. Conventional grating couplers achieve at best 50% efficiency in coupling light in a desired direction due to conventional grating couplers coupling light in both the desired direction and an opposite direction. Various attempted solutions to this problem provide photonic structures that very difficult to fabricate. Through applied effort, ingenuity, and innovation, many deficiencies of prior grating couplers and corresponding fabrication techniques have been solved by developing solutions that are structured in accordance with the embodiments of the present invention, many examples of which are described in detail herein.

### BRIEF SUMMARY OF EXAMPLE EMBODIMENTS

Example embodiments provide methods, systems, apparatuses, computer program products and/or the like for fabrication of three-level structures. In various embodiments, the three-level structures are at least part of photonic structures or elements. For example, a three-level structure may be part of grating coupler or other photonic element. In various embodiments, three-level structures are structures with three levels of material thickness: no material, thin material, and thick material. In various embodiments, the fabrication method disclosed herein is deterministic and easily controllable.

According to an aspect, a method for fabrication of three-level structures is provided. In an example embodiment, the method includes forming a mold on a substrate, wherein the mold comprises narrower regions and broader regions defined at least in part by boundaries that extend out from the substrate a mold distance. The method further includes depositing an amount of material that completely fills in the narrower regions of the mold and partially fills in the broader regions of the mold. The method further includes etching the deposited material such that the deposited material extends at most the mold distance out from the substrate. The method further includes removing the mold such that a three-level structure remains. The three-level structure comprises one or more areas of a first thickness of no material, one or more areas of a second thickness of thin material, and one or more areas of a third thickness of thick material.

In an example embodiment, the mold is a mold is a planar film with voids extending to the substrate comprised of at least one of glass, silicon, photoresist, and/or lithographic resist.

In an example embodiment, the narrower regions correspond to the one or more areas of the third thickness.

In an example embodiment, the broader regions correspond to the one or more areas of the second thickness.

In an example embodiment, the depositing comprises a conformal deposition method.

In an example embodiment, the conformal deposition method is atomic layer deposition (ALD).

In an example embodiment, the method further includes coating the deposited material with a protective layer that completely fills in the broader regions and covers the full narrower regions.

In an example embodiment, the coating comprises spin-coating the deposited material with the protective layer.

In an example embodiment, the coating comprises spray-coating the deposited material with the protective layer.

In an example embodiment, the protective layer is comprised of photoresist.

In an example embodiment, the etching comprises removing at least some overburden.

In an example embodiment, the etching comprises using at least one of reactive ion etching (RIE) and/or chemical/mechanical polishing (CMP).

In an example embodiment, the deposited material comprises at least one of metallic compounds, dielectric compounds, silicon (Si), silicon nitride (SiN), silicon oxide (SiO2), titanium oxide (TiO2), tantalum oxide (TaO2), aluminum oxide (Al203), and/or hafnium oxide (HfO2).

In an example embodiment, the amount of material is deposited in a layer characterized by a layer depth, the narrower regions comprise gaps defined by respective boundaries having respective widths that are less than twice the layer depth, and the broader regions comprise gaps defined by respective boundaries having respective widths that are greater than twice the layer depth.

In an example embodiment, the three-level structure is formed as a single lithographic layer.

According to an aspect, an apparatus for a three-level structure is provided. The apparatus comprises a three-level structure. The three-level structure comprises one or more first areas characterized by a first thickness of no material, one or more second areas characterized by a second thickness of thin material, and one or more third areas characterized by a third thickness of thick material.

In an example embodiment, the three-level structure comprises at least one of metallic compounds, dielectric compounds, silicon (Si), silicon nitride (SiN), silicon oxide (SiO2), titanium oxide (TiO2), tantalum oxide (TaO2), aluminum oxide (Al203), and/or hafnium oxide (HfO2).

In an example embodiment, the three-level structure is formed as a single lithographic layer.

According to an aspect, a system comprising a three-level structure is provided. The system comprises a confinement apparatus, a controller for controlling the confinement apparatus, and a diffractive optical element comprising a three-level structure. The three-level structure comprises one or more first areas characterized by a first thickness of no material, one or more second areas characterized by a second thickness of thin material, and one or more third areas characterized by a third thickness of thick material.

In an example embodiment, the diffractive optical element is a grating coupler.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a cross-sectional view of a three-level structure, according to an example embodiment.

FIG. 2 is a cross-sectional view of a method of fabrication of a three-level structure, according to an example embodiment.

FIG. 3 is a flow chart showing an example method for fabrication of a three-level structure, according to an example embodiment.

FIG. 4 is a schematic diagram illustrating an example quantum computing system comprising a three-level structure, according to an example embodiment.

FIG. 5 provides a schematic diagram of an example controller of a quantum computer configured to perform one or more deterministic reshaping and/or reordering functions, according to various embodiments.

FIG. 6 provides a schematic diagram of an example computing entity of a quantum computer system that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally,” “substantially,” and “approximately” refer to within engineering and/or manufacturing tolerances and/or within user measurement capabilities, unless otherwise indicated. Like numbers refer to like elements throughout.

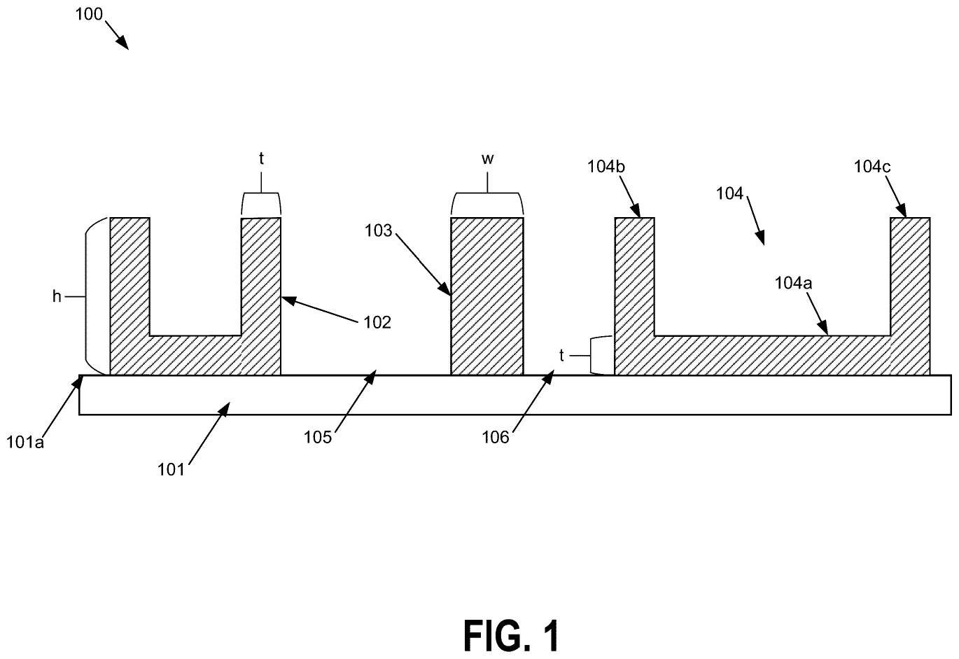

In various embodiments, three-level structures are fabricated in a single lithographic step. In various embodiments, three-level structures are fabricated in a single lithographic layer. In various embodiments, three-level structures have one or more first areas characterized by a first thickness of no material, one or more second areas characterized by a second thickness of thin material, and one or more third areas characterized by a third thickness of thick material (as described herein with respect to FIG. 1). The thinness of the thin material and the thickness of the thick material are relative to one another. In other words, the thin material is referred to as thin herein because it is thinner than the third thickness and the thick material is referred to as thick herein because it is thicker than the second thickness.

There is a need for more efficient optical elements such as grating couplers. Simple grating couplers result in symmetrical scattering of light (e.g., 50% of the light scatters upward and 50% of the light scatters downward). Therefore, breaking out-of-plane symmetry of a grating coupler is critical for high coupling efficiency. Some conventional solutions include using underlying mirrors, two-layer gratings, partially etched gratings, and multi-level gratings. Partially etched grating couplers require specific etch depth and add complexity and are therefore difficult to fabricate. Grating couplers with bottom reflectors have mirrors underneath the grating coupler, the spacing of which from the grating coupler is critical to achieve constructive interference of the coupled light. Conventional fabrication of multi-level etched grating couplers requires multiple lithographic steps and partial etches; while they have high efficiency, they are difficult to fabricate. Various conventional methods suffer from being difficult to implement.

Various embodiments provide technical solutions to these technical problems. In various embodiments, fabrication of three-level structures in a single lithographic step is provided. In various embodiments, a mold is formed on a substrate. For example, the mold may be a mold is a planar film with voids extending to the substrate (e.g., a damascene mold) formed of glass, silicon, photoresist, lithographic resist, and/or other materials. In various embodiments, the mold includes narrower features that correspond to future areas of thick material and broader features that correspond to future areas of thin material. In various embodiments, an amount of material is deposited that fully fills in the narrower features of the mold. For example, the material may be deposited using a conformal deposition method such as atomic layer deposition (ALD). In various embodiments, the deposited material is coated (e.g., via spin-coating and/or spray-coating) with a protective layer to fill in the broader gaps and cover the narrower gaps. In various embodiments, the protective layer may be photoresist. In various embodiments, using dry etching, reactive ion etching (RIE), and/or chemical/mechanical polishing (CMP), the coating and some of the deposited material (e.g., any overburden) are removed down to the level of the original mold (e.g., down to a mold distance away from the substrate). In various embodiments, the protective layer protects the deposited material, for example, when using RIE, since the thin layer of deposited material at the substrate may be the same thickness as the material to be removed from on top of the mold. In various embodiments, the mold is removed, and the three-level structure remains on the substrate.

The size scales of the deposited material may vary based on application. In various embodiments, the thickness of the thick material may vary from tens of nanometers to tens of microns. In various embodiments, the thickness of the thin material may vary from a few nanometers to a few microns. In various embodiments, the gaps between the materials may vary from tens of nanometers to tens of microns (e.g., if fabricating for a grating). In various embodiments, such as in the case of fabricating for other uses, the size of the substrate chip imposes the upper limit on the gaps between the deposited material.

Thus, various embodiments provide technical improvements to the fields of three-level structures and systems that include three-level structures and/or other optical components that may be replaced with three-level structures.

### Exemplary Three-Level Structure and Fabrication Thereof

FIG. 1 is a cross-sectional view of a three-level structure 100, according to an example embodiment. In various embodiments, the three-level structure 100 is a grating coupler, a diffractive optical element (for use with free space modes or guided modes), a metasurface, and/or other photonic or optical component. For example, the structure elements of the three-level structure may be configured to diffract light, induce phase shifts in light, and/or affect various properties of light that interacts therewith. In various embodiments, the three-level structure 100 is a passive photonic or optical component. In some embodiments, the three-level structure 100 is an active photonic or optical component.

In various embodiments, one or more three-level structures are formed and/or disposed on a substrate 101. In various embodiments, the substrate 101 is a surface or layer of an atomic object confinement apparatus and/or another substrate that is configured to be secured with respect to the atomic object confinement apparatus. In various embodiments, the substrate 101 has a surface 101a. In various embodiments, the substrate 101 is comprised of a substrate material, such as silicon oxide (SiO2), aluminum oxide (Al203), germanium (Ge), silicon carbide (SiC), and/or other materials.

FIG. 1 shows a three-level structure having structure elements 102, 103, and 104 formed of a photon interaction material and gaps 105, 106. In various embodiments, three-level structures are comprised of one or more first areas (e.g., gaps 105, 106) characterized by a first thickness of the photon interaction material, one or more second areas (e.g., structure elements 102, 104) characterized by a second thickness of the photon interaction material, and/or one or more third areas (e.g., structure element 103) characterized by a third thickness of the photon interaction material. In various embodiments, the photon interaction material comprises one or more of metallic compounds (e.g., for reflective applications), dielectric compounds, silicon (Si), silicon nitride (SiN), silicon oxide (SiO2), titanium oxide (TiO2), tantalum oxide (TaO2), hafnium oxide (HfO2), and/or other materials.

In various embodiments, the structure elements 102, 104 of the three-level structure that are disposed in and/or form the second areas (e.g., characterized by the second thickness of the photon interaction material) are U-shaped. For example, the structure element 102 of the three-level structure includes a structure height h. In various embodiments, the structure height h is within a range from tens of nanometers to tens of microns. For example, in various embodiments, the structure height h is a value in a range of 10 nm to 90 μm, as appropriate for the application. The structure height h may be referred to as the “third thickness” and/or the “thick material” throughout the present disclosure. For example, the height h defines the third thickness. In various embodiments, the structure element 102 of the three-level structure 100 has a deposition thickness t (e.g., such as the deposition thickness t shown for the structure element 104), wherein t may range from several nanometers to several microns. For example, in various embodiments, the deposition thickness t is a value in a range of 1 nm to 10 μm, as appropriate for the application. The deposition thickness t may be referred to as the “second thickness” and/or the “thin material” throughout the present disclosure. For example, the deposition thickness t defines the second thickness. Notably, 0<t<h.

In various embodiments, the three-level structure includes one or more U-shaped structure elements, such as the structure elements 102, 104. For example, the structure element 104 has a “base” 104a and “legs” 104b and 104c. The structure element 102, and/or any other U-shaped structure, can be understood have elements similar to the elements 104a-104c of the structure element 104. In various embodiments, the base 104a of the structure element 104 extends a deposition thickness t perpendicular to the surface 101a of the substrate 101. Similarly, in various embodiments, the base of the structure element 102 extends a deposition thickness t perpendicular to the surface 101a of the substrate 101. In various embodiments, the legs 104b and 104c of the structure element 104 extend a structure height h perpendicular to the surface 101a of the substrate 101. Similarly, in various embodiments, the legs of the structure element 102 extend a structure height h perpendicular to the surface 101a of the substrate 101. In various embodiments, the total width of the structure element 104 (e.g., the distance from leg 104b to leg 104c or vice versa) is greater than the total width of the structure element 102 (e.g., the distance from the first leg of structure element 102 to the second leg of structure element 102). In various embodiments, the total width of the structure element 102 (e.g., the distance from the first leg of structure element 102 to the second leg of structure element 102) is greater than the total width of the structure element 104 (e.g., the distance from leg 104b to leg 104c or vice versa). For example, the U-shaped structure elements may be formed in a variety of widths, as appropriate for the application.

In various embodiments, the structure element 103 of the three-level structure 100 is characterized by the structure height h in a direction transverse and/or perpendicular to the surface 101a of the substrate 101. For example, the structure element 103 extends out from the surface 101a of the substrate 101 a structure height h. In various embodiments, the structure element 103 of the three-level structure has a width w that is less than or equal to two times the deposition thickness t (e.g., a width w≤2t) in a direction parallel to the surface 101a of the substrate 101. For example, the structure element 103 extends along the surface 101a of the substrate a width w that is at most twice the deposition thickness t.

In various embodiments, the three-level structure 100 may include one or more pillar-shaped structures, such as structure element 103. In an example embodiment, the width w of each pillar-shaped structure is the same. For example, each pillar-shaped structure may have the same width w (and the same structure height h). In various embodiments, the pillar-shaped structures may have various widths w, with each of the various widths w characterized as being in the range of zero to two times the deposition thickness t (e.g., 0<w≤2t). For example, in some embodiments, some pillar-shaped structures may have widths that are different from some other of the pillar-shaped structures.

### Exemplary Methods for Fabrication of a Three-Level Structure

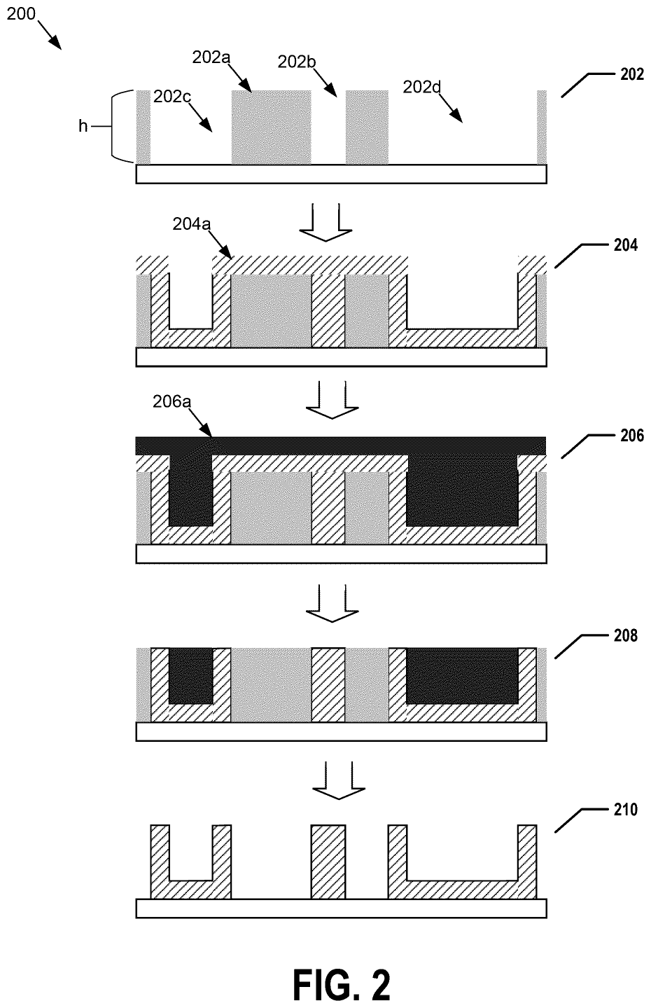

FIG. 2 is a cross-sectional view of a method of fabrication of a three-level structure, according to an example embodiment. At step 202, a mold 202a may be formed on a substrate (e.g., such as the substrate 101 in FIG. 1). In various embodiments, the mold 202a has multiple components. For example, in FIG. 2, four structures comprised of the mold 202a are formed on the substrate. In some embodiments, mold has a height h which extends a mold distance away from the surface of the substrate. In some embodiments, if the mold 202a is formed on the substrate, there will remain one or more regions of no mold. In some embodiments, the one or more regions of no mold can be characterized as “narrower” regions 202b and/or “broader” regions 202c and 202d. In some embodiments, for example, the narrower regions are characterized as “narrower” because they are narrower relative to the broader regions. In some embodiments, for example, the broader regions are characterized as “broader” because they are broader relative to the narrower regions. The narrower regions 202b have widths in a direction parallel to the surface 101a of the substrate 101 that are no more than two times the deposition thickness t. The broader regions 202c, 202d have widths in a direction parallel to the surface 101a of the substrate 101 that are greater than two times the deposition thickness t.

At step 204, some amount of source material 204a (e.g., photon interaction material) may be deposited over the substrate and the mold to a deposition thickness t. In various embodiments, the source material 204a (e.g., photon interaction material) is deposited conformally (e.g., via atomic layer deposition (ALD), chemical vapor deposition (CVD), and/or the like). At step 206, a protective layer 206a may be applied to the deposited material (e.g., photon interaction material). At step 208, some portion of the protective layer and the deposited material (e.g., photon interaction material) may be removed via etching. For example, any overburden of the deposited material (e.g., photon interaction material) may be removed such that the remaining mold 202a, source material 204a (e.g., photon interaction material), and protective layer 206a collectively extend a height h perpendicular to the surface 101a of the substrate 101.

At step 210, the remaining mold and protective layer may be removed, leaving a three-level structure with one or more areas of a first thickness of no material (e.g., no remaining deposited material), one or more areas of a second thickness of thin material (e.g., the deposition thickness t), and/or one or more areas of a third thickness of thick material (e.g., the structure height h). In various embodiments, steps 202-210 are performed as a single lithographic step. In various embodiments, the three-level structure is formed as a single lithographic layer.

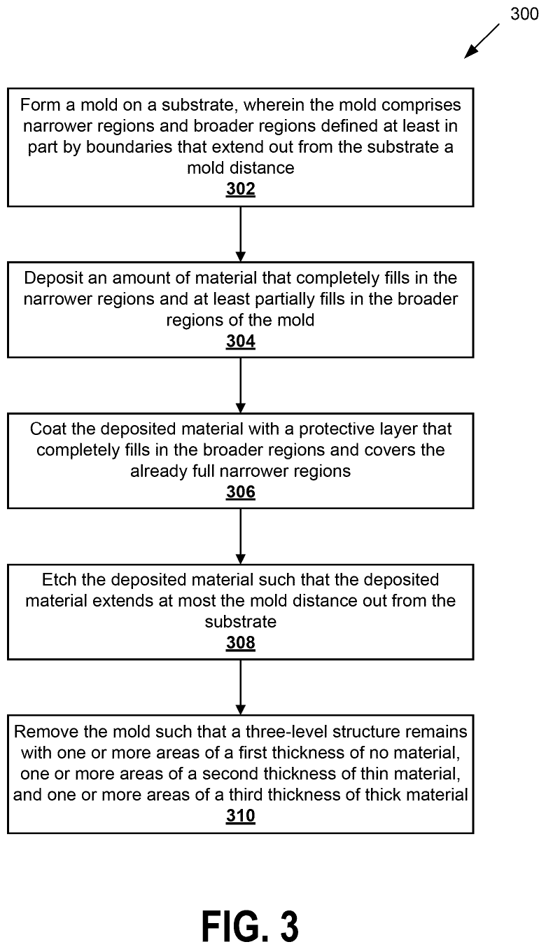

FIG. 3 is a flow chart showing an example method 300 for fabrication of a three-level structure in a single lithographic step, according to an example embodiment. At step 302, a mold (e.g., such as the mold 202a) is formed and/or disposed on a substrate (e.g., such as the substrate 101 in FIG. 1). In various embodiments, the mold is formed and/or disposed on the substrate such as shown in step 202 of FIG. 2. In various embodiments, the mold 202a has multiple components. For example, in FIG. 2, four structures comprised of the mold 202a are formed on the substrate. In some embodiments, mold has a height h which extends a mold distance away from the surface of the substrate. In some embodiments, if the mold 202a is formed on the substrate, there will remain one or more regions of no mold. In some embodiments, the one or more regions of no mold can be characterized as “narrower” regions 202b and/or “broader” regions 202c and 202d. The narrower regions 202b are characterized by having widths in a direction parallel to the surface 101a of the substrate 101 that are no more than two times the deposition thickness t. The broader regions 202c, 202d are characterized by having widths in a direction parallel to the surface 101a of the substrate 101 that are greater than two time the deposition thickness t. Throughout the present disclosure, the narrower regions are characterized as being “narrower” relative to the broader regions and the broader regions are characterized as being “broader” relative to the narrower regions.

In various embodiments, the “mold distance” refers to the height of the mold extends outward from the surface of the substrate. In various embodiments, the mold is mold is a planar film with voids extending to the substrate. In various embodiments, the mold is a damascene mold. In various embodiments, the mold is comprised of glass, silicon, photoresist, lithographic resist, and/or other materials. For example, the mold comprises a material that may be selectively etched away from the photon interaction material. In various embodiments, the mold is formed via exposure and/or developing of a polymer resist using photolithography and/or electron beam lithography. In various embodiments, the mold is formed via nanoimprint lithography. In various embodiments, the mold is formed via a multi-step process including a lithographic step to serve as a mask and then etching of the mold material. In various embodiments, the mold is formed via additive deposition of the mask material, for example, using a lithographically patterned polymer as a deposition mask (e.g., a “liftoff” process). In various embodiments, the mold is formed via direct-write etching of the mask material using a focused ion beam.

At step 304, photon interaction material (e.g., such as the photon interaction material 204a) is deposited on the mold. For example, a layer of photon interaction material having a thickness substantially equal to the deposition thickness t is deposited on the mold. In various embodiments, the photon interaction material is deposited via a conformal deposition method. In various embodiments, the conformal deposition method is atomic layer deposition (ALD) or chemical vapor deposition (CVD). In various embodiments, the layer of photon interaction material that is deposited completely fills in the narrower regions formed in the mold and at least partially fills in the broader regions formed in the mold. In various embodiments, the material is deposited such as shown in step 204 of FIG. 2.

In various embodiments, the deposited photon interaction material is comprised of metallic compounds (e.g., for reflective applications), dielectric compounds, silicon (Si), silicon nitride (SiN), silicon oxide (SiO2), titanium oxide (TiO2), tantalum oxide (TaO2), hafnium oxide (HfO2), indium titanium oxide (ITO), and/or other materials. In various embodiments, the amount of material is deposited in a layer characterized by a layer depth, wherein the narrower regions comprise gaps defined by respective boundaries having respective widths that are greater than twice the layer depth, and wherein the broader regions comprise gaps defined by respective boundaries having respective widths that are less than twice the layer depth. For example, in various embodiments, the layer depth is substantially equal to the deposition thickness t.

At step 306, the deposited material (e.g., photon interaction material) is coated with a protective layer (e.g., such as the protective layer 206a) that completely fills in the broader regions left by the mold and covers the already full narrower regions. In various embodiments, the coating is applied such as shown in step 206 of FIG. 2. In various embodiments, the protective layer is comprised of photoresist and/or other materials. In various embodiments, the protective layer is applied via spin-coating. In various embodiments, the protective layer is applied via spray-coating. In various embodiments, applying the protective layer is optional.

At step 308, the deposited material (e.g., including the protective layer) is etched such that the deposited material extends at most the mold distance out from the substrate. In various embodiments, the etching is performed to a degree such as shown in step 208 of FIG. 2. For example, any overburden of the photon interaction material may be removed such that the mold 202a, photon interaction material 204a, and the protective layer 206a collectively extend a height h (e.g., which may be substantially equal to the mold distance) out from the surface 101a of the substrate 101.

In various embodiments, the etching is done via reactive ion etching (RIE). In various embodiments, the etching is done via chemical/mechanical polishing (CMP). In various embodiments, the etching removes at least some (e.g., any) overburden of deposited material and protective layer. In various embodiments, such as when etching via RIE, the protective layer prevents the material at the bottom of the U-shaped structure elements of the three-level structure.

At step 310, the mold is removed. In various embodiments, the mold is removed such that a three-level structure remains with one or more areas of a first thickness of no material (e.g., no remaining deposited material), one or more areas of a second thickness of thin material (e.g., the thickness t), and/or one or more areas of a third thickness of thick material (e.g., the thickness h). In various embodiments, the removal of the mold is performed to a degree such as shown in step 210 of FIG. 2. In various embodiments, any remaining portions of the protective layer 206a may also be removed in the same step as the mold removal or as a different step, as appropriate for the application and the material used as the mold material and as the protective layer.

In various embodiments, the mold and/or remaining portions of the protective layer may be removed via various methods. In various embodiments, for example, if the mold is a polymer resist, the mold may be removed using a solvent bath (e.g., acetone, a solvent specifically designed to remove the resist, etc.). In various embodiments, polymer resists are selectively removed using oxygen (O2) plasma etching. In various embodiments, for example, if the mask is comprised of a “hard” material (e.g., such as a dielectric material and/or a metal, etc.), the mask is removed via wet and/or dry plasma etching using a process that removes the mask while having minimal impact on the substrate and device materials.

In various embodiments, steps 302-310 are performed as a single lithographic step. In various embodiments, the three-level structure is formed as a single lithographic layer.

### Technical Advantages

Various embodiments provide technical advantages, as described herein. In various embodiments, the fabrication method described herein is easily repeatable. In various embodiments, the fabrication method described herein results in systems with high accuracy in up to all dimensions. In various embodiments, the fabrication method described herein results in systems that can be co-fabricated with other single-layer features or waveguides. Applications of this fabrication method include more efficient grating couplers and diffractive optical elements such as diffractive free space optics.

### Exemplary Quantum Computing System Comprising an Atomic Object Confinement Apparatus

Various embodiments provide three-level structures and methods for fabrication thereof. Various embodiments provide systems that include one or more of such three-level structures. Various embodiments provide various optical, electro-optical, opto-mechanical systems that include such three-level structures. One example system is a quantum computing system.

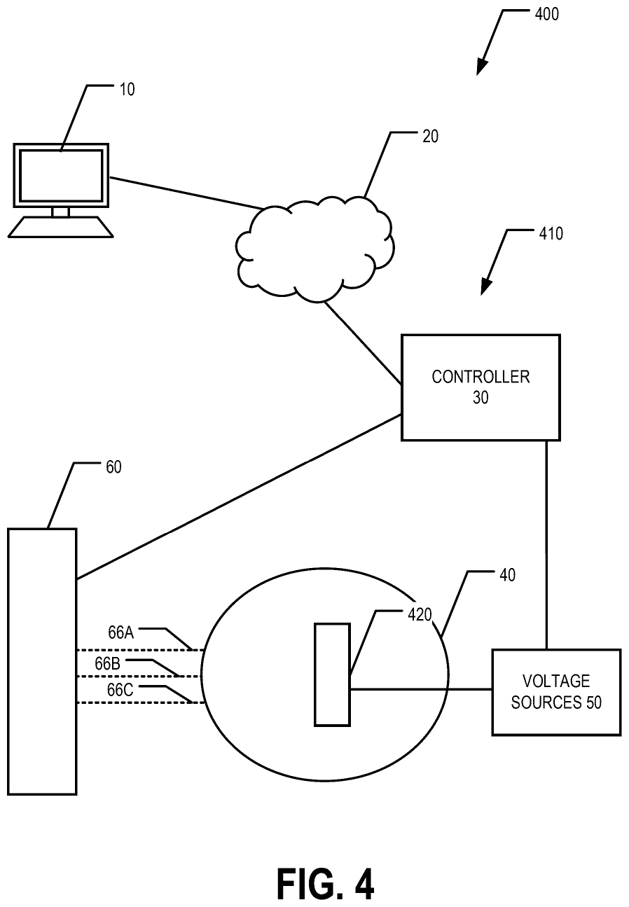

FIG. 4 provides a schematic diagram of an example quantum computing system 500 comprising an atomic object confinement apparatus 420 (e.g., an ion trap and/or the like), in accordance with an example embodiment. In various embodiments, the atomic object confinement apparatus 420 is configured to confine one or more atomic objects (e.g., neutral or ionic atoms; neutral, ionic, or multipolar molecules; and/or the like). For example, FIG. 4 schematically illustrates an example quantum charge-coupled device (QCCD)-based quantum computer. However, various three-level structures 100 may be incorporated into various types of quantum computers (e.g., for providing manipulation signals for qubit interaction, cooling, and/or the like) and/or various types of atomic systems (e.g., for providing manipulation signals for trapped particle/ion/atom/molecule interaction).

As shown in FIG. 1, a one or more three-level structures are formed on a substrate 101. In various embodiments, the substrate 101 is a surface of the atomic object confinement apparatus and/or another substrate that is configured to be secured with respect to the atomic object confinement apparatus. In various embodiments, at least a portion of some three-level structures are configured for providing manipulation signals (e.g., laser beams/pulses and/or the like) to respective atomic object positions defined at least in part by the atomic object confinement apparatus 420 and/or for collecting light (e.g., fluorescence) emitted by one or more atomic objects confined at respective atomic object positions.

For example, in various embodiments, an atomic object confinement apparatus having one or more three-level structures formed and/or disposed on the surface of the atomic object confinement apparatus or a confinement apparatus assembly comprising an atomic object confinement apparatus and another substrate configured to be secured with respect to the atomic object confinement apparatus and having one or more three-level structures formed and/or disposed on a surface thereof is provided. In various embodiments, each three-level structure is formed and/or configured for use in providing one or more manipulation signals for use in performing one or more functions (photoionization, state preparation, qubit detection and/or reading, cooling, shelving, repumping, single qubit gates, two qubit gates, and/or the like) of a confined atomic object quantum computer (e.g., a QCCD-based quantum computer).

For example, a three-level structure 100 may be part of an optical path 66 (e.g., 66A, 66B, 66C) configured to provide one or more manipulation signals to a respective atomic object position defined at least in part by the atomic object confinement apparatus 420.

In various embodiments, the quantum computing system 400 comprises a computing entity 10 and a quantum computer 410. In various embodiments, the quantum computer 410 comprises a controller 30, a cryostat and/or vacuum chamber 40 enclosing a confinement apparatus 420 (e.g., an ion trap), and one or more manipulation sources 60. For example, the cryostat and/or vacuum chamber 40 may be a pressure-controlled chamber. In an example embodiment, the manipulation signals generated by the manipulation sources 60 are provided to the interior of the cryostat and/or vacuum chamber 40 (where the atomic object confinement apparatus 420 is located) via corresponding optical paths 66 (e.g., 66A, 66B, 66C). In an example embodiment, the one or more manipulation sources 60 may comprise one or more lasers (e.g., optical lasers, microwave sources, and/or the like). In various embodiments, each manipulation source is configured to generate a manipulation signal having a respective characteristic wavelength in the microwave, infrared, visible, or ultraviolet portion of the electromagnetic spectrum. In various embodiments, the one or more manipulation sources 60 are configured to manipulate and/or cause a controlled quantum state evolution of one or more atomic objects within the confinement apparatus. For example, in an example embodiment, wherein the one or more manipulation sources 60 comprise one or more lasers, the lasers may provide one or more laser beams to atomic objects trapped within the confinement apparatus 420 within the cryostat and/or vacuum chamber 40. For example, the manipulation sources 60 may be configured to generate one or more beams that may be used to initialize an atomic object into a state of a qubit space such that the atomic object may be used as a qubit of the confined atomic object quantum computer, perform one or more gates on one or more qubits of the confined atomic object quantum computer, read and/or determine a state of one or more qubits of the confined atomic object quantum computer, and/or the like.

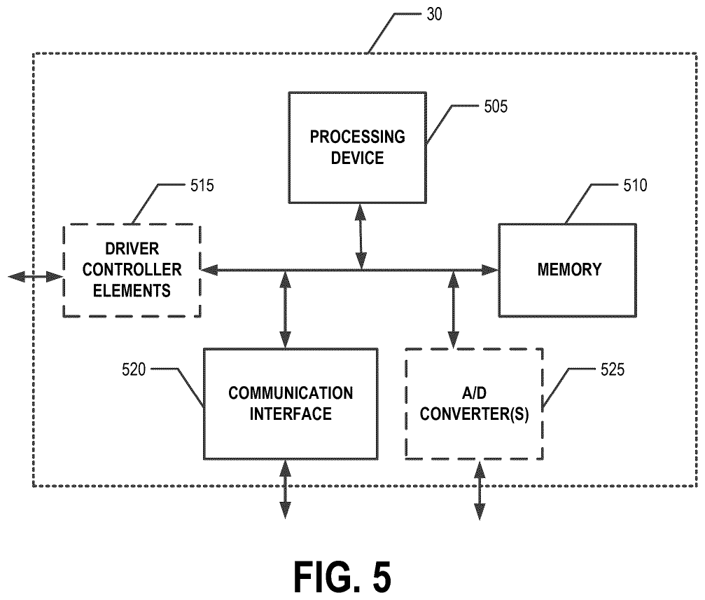

In various embodiments, the quantum computer 410 comprises an optics collection system configured to collect and/or detect photons generated by qubits (e.g., during reading procedures). The optics collection system may comprise one or more optical elements (e.g., three-level structures, lenses, mirrors, waveguides, fiber optics cables, and/or the like) and one or more photodetectors. In various embodiments, the optical elements include diffractive optical elements such as grating couplers. In various embodiments, grating couplers may be comprised of one or more three-level structures. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer. In various embodiments, the detectors may be in electronic communication with the controller 30 via one or more A/D converters 525 (see FIG. 5) and/or the like. For example, an atomic object being read and/or having its quantum state determined may emit an emitted signal, at least a portion of which is incident on a collection array of meta material structures formed and/or disposed on the surface of the atomic object confinement apparatus 420. The emitted signal being incident on the collection array of meta material structures induces the meta material structures to emit a detected signal directed toward and/or focused at collection optics of the atomic object confinement apparatus. The collection optics are configured to provide the collection signal to a photodetector.

In various embodiments, the quantum computer 410 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding potential generating elements (e.g., electrodes) of the confinement apparatus 420, in an example embodiment.

In various embodiments, a computing entity 10 is configured to allow a user to provide input to the quantum computer 410 (e.g., via a user interface of the computing entity 10) and receive, view, and/or the like output from the quantum computer 410. The computing entity 10 may be in communication with the controller 30 of the quantum computer 410 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the controller 30 can understand and/or implement.

In various embodiments, the controller 30 is configured to control the voltage sources 50, cryostat system and/or vacuum system controlling the temperature and pressure within the cryostat and/or vacuum chamber 40, manipulation sources 60, and/or other systems controlling various environmental conditions (e.g., temperature, pressure, and/or the like) within the cryostat and/or vacuum chamber 40 and/or configured to manipulate and/or cause a controlled evolution of quantum states of one or more atomic objects within the confinement apparatus. For example, the controller 30 may cause a controlled evolution of quantum states of one or more atomic objects within the confinement apparatus to execute a quantum circuit and/or algorithm. For example, the controller 30 may cause a reading procedure comprising coherent shelving to be performed, possibly as part of executing a quantum circuit and/or algorithm. In various embodiments, the atomic objects confined within the confinement apparatus are used as qubits of the quantum computer 410.

### Exemplary Controller

In various embodiments, a confinement apparatus 420 is incorporated into a system (e.g., a quantum computer 410) comprising a controller 30. In various embodiments, the controller 30 is configured to control various elements of the system (e.g., quantum computer 410). For example, the controller 30 may be configured to control the voltage sources 50, a cryostat system and/or vacuum system controlling the temperature and pressure within the cryostat and/or vacuum chamber 40, manipulation sources 60, cooling system, and/or other systems controlling the environmental conditions (e.g., temperature, humidity, pressure, and/or the like) within the cryostat and/or vacuum chamber 40 and/or configured to manipulate and/or cause a controlled evolution of quantum states of one or more atomic objects confined by the atomic object confinement apparatus 420. In various embodiments, the controller 30 may be configured to receive signals from one or more optics collection systems.

As shown in FIG. 5, in various embodiments, the controller 30 may comprise various controller elements including processing elements 505, memory 510, driver controller elements 515, a communication interface 520, analog-digital converter elements 525, and/or the like. For example, the processing elements 505 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing element 505 of the controller 30 comprises a clock and/or is in communication with a clock.

For example, the memory 510 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 510 may store a queue of commands to be executed to cause a quantum algorithm and/or circuit to be executed (e.g., an executable queue), qubit records corresponding the qubits of quantum computer (e.g., in a qubit record data store, qubit record database, qubit record table, and/or the like), a calibration table, computer program code (e.g., in a one or more computer languages, specialized controller language(s), and/or the like), and/or the like. In an example embodiment, execution of at least a portion of the computer program code stored in the memory 510 (e.g., by a processing element 505) causes the controller 30 to perform one or more steps, operations, processes, procedures and/or the like described herein for providing manipulation signals to atomic object locations and/or collecting, detecting, capturing, and/or measuring indications of emitted signals emitted by atomic objects located at corresponding atomic object locations of the atomic object confinement apparatus 420.

In various embodiments, the driver controller elements 515 may include one or more drivers and/or controller elements each configured to control one or more drivers. In various embodiments, the driver controller elements 515 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 505). In various embodiments, the driver controller elements 515 may enable the controller 30 to operate a voltage sources 50, manipulation sources 60, cooling system, and/or the like. In various embodiments, the drivers may be laser drivers configured to operate one or manipulation sources 60 to generate manipulation signals; vacuum component drivers; drivers for controlling the flow of current and/or voltage applied to electrodes used for maintaining and/or controlling the trapping potential of the atomic object confinement apparatus 420 (and/or other drivers for providing driver action sequences to potential generating elements of the atomic object confinement apparatus); cryostat and/or vacuum system component drivers; cooling system drivers, and/or the like. In various embodiments, the controller 30 comprises means for communicating and/or receiving signals from one or more optical receiver components (e.g., photodetectors of the optics collection system). For example, the controller 30 may comprise one or more analog-digital converter elements 525 configured to receive signals from one or more optical receiver components (e.g., a photodetector of the optics collection system), calibration sensors, and/or the like.

In various embodiments, the controller 30 may comprise a communication interface 520 for interfacing and/or communicating with a computing entity 10. For example, the controller 30 may comprise a communication interface 520 for receiving executable instructions, command sets, and/or the like from the computing entity 10 and providing output received from the quantum computer 410 (e.g., from an optical collection system) and/or the result of a processing the output to the computing entity 10. In various embodiments, the computing entity 10 and the controller 30 may communicate via a direct wired and/or wireless connection and/or via one or more wired and/or wireless networks 20.

### Exemplary Computing Entity

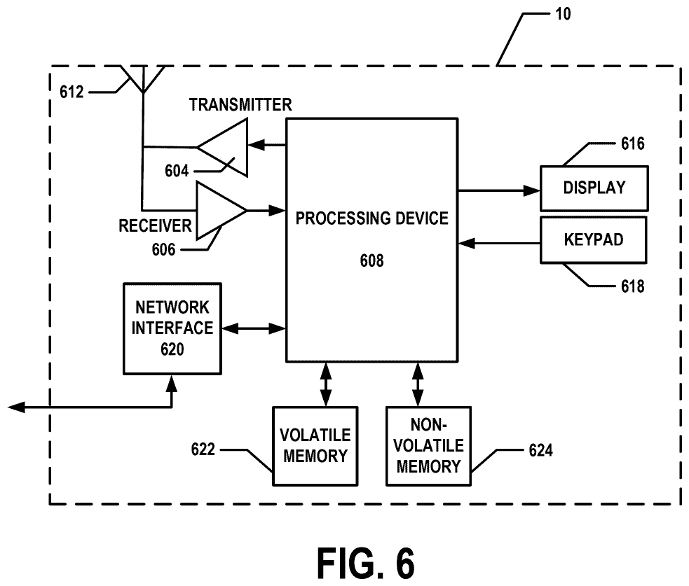

FIG. 6 provides an illustrative schematic representative of an example computing entity 10 that can be used in conjunction with embodiments of the present invention. In various embodiments, the computing entity 10 is a classical or semiconductor-based computing apparatus that is part of the quantum computing system 400.

In various embodiments, the computing entity 10 is configured to allow a user to provide input to the quantum computer 410 (e.g., via a user interface of the computing entity 10) and receive, display, analyze, and/or the like output from the quantum computer 410.

As shown in FIG. 6, a computing entity 10 can include an antenna 612, a transmitter 604 (e.g., radio), a receiver 606 (e.g., radio), and a processing element 608 that provides signals to and receives signals from the transmitter 604 and receiver 606, respectively. The signals provided to and received from the transmitter 604 and the receiver 606, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

In various embodiments, the computing entity 10 comprises one or more network interfaces 620 configured for communicating via one or more wired and/or wireless computer networks.

The computing entity 10 may also comprise a user interface device comprising one or more user input/output interfaces (e.g., a display 616 and/or speaker/speaker driver coupled to a processing element 608 and a touch screen, keyboard, mouse, and/or microphone coupled to a processing element 608). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 618 (hard or soft), a touch display, voice/speech or motion interfaces, scanners, readers, or other input device. In embodiments including a keypad 618, the keypad 618 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 622 and/or non-volatile storage or memory 624, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Conclusion

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A method comprising:
forming a mold on a substrate, wherein the mold comprises narrower regions and broader regions defined at least in part by boundaries that extend out from the substrate a mold distance;
depositing an amount of material that completely fills in the narrower regions of the mold and partially fills in the broader regions of the mold;
etching the deposited material such that the deposited material extends at most the mold distance out from the substrate; and
removing the mold such that a three-level structure remains with one or more areas of a first thickness of no material, one or more areas of a second thickness of thin material, and one or more areas of a third thickness of thick material.

2. The method of claim 1, wherein the mold is a planar film with voids extending to the substrate comprised of at least one of:
glass;
silicon;
photoresist; or
lithographic resist.

3. The method of claim 1, wherein the narrower regions correspond to the one or more areas of the third thickness.

4. The method of claim 1, wherein the broader regions correspond to the one or more areas of the second thickness.

5. The method of claim 1, wherein the depositing comprises a conformal deposition method.

6. The method of claim 5, wherein the conformal deposition method is atomic layer deposition (ALD).

7. The method of claim 1, further comprising coating the deposited material with a protective layer that completely fills in the broader regions and covers the full narrower regions.

8. The method of claim 7, wherein the coating comprises spin-coating the deposited material with the protective layer.

9. The method of claim 7, wherein the coating comprises spray-coating the deposited material with the protective layer.

10. The method of claim 1, wherein the protective layer is comprised of photoresist.

11. The method of claim 1, wherein the etching comprises removing at least some overburden.

12. The method of claim 1, wherein the etching comprises using at least one of:
reactive ion etching (RIE); or chemical/mechanical polishing (CMP).

13. The method of claim 1, wherein the deposited material comprises at least one of:
metallic compounds;
dielectric compounds;
silicon (Si);
silicon nitride (SiN);
silicon oxide (SiO2);
titanium oxide (TiO2);
tantalum oxide (TaO2);
aluminum oxide (Al2O3); or hafnium oxide (HfO2).

14. The method of claim 1, wherein the amount of material is deposited in a layer characterized by a layer depth, the narrower regions comprise gaps defined by respective boundaries having respective widths that are less than twice the layer depth, and the broader regions comprise gaps defined by respective boundaries having respective widths that are greater than twice the layer depth.

15. The method of claim 1, wherein the three-level structure is formed as a single lithographic layer.

16. An apparatus comprising:
a three-level structure, the three-level structure comprising:
one or more first areas characterized by a first thickness of no material;
one or more second areas characterized by a second thickness of thin material; and
one or more third areas characterized by a third thickness of thick material.

17. The apparatus of claim 13, wherein the three-level structure is comprised of at least one of:
metallic compounds;
dielectric compounds;
silicon (Si);
silicon nitride (SiN);
silicon oxide (SiO2);
titanium oxide (TiO2);
tantalum oxide (TaO2);
aluminum oxide (Al2O3); or
hafnium oxide (HfO2).

18. The apparatus of claim 13, wherein the three-level structure is formed as a single lithographic layer.

19. A system comprising:
a confinement apparatus;
a controller for controlling the confinement apparatus; and
a diffractive optical element comprising a three-level structure, the three-level structure comprising:
one or more first areas characterized by a first thickness of no material;
one or more second areas characterized by a second thickness of thin material; and
one or more third areas characterized by a third thickness of thick material.

20. The system of claim 19, wherein the diffractive optical element is a grating coupler.
